(19) United States
(12) Patent Application Publication
(10) Pub. No.: US 2021/0226409 A1
(43) Pub. Date: Jul. 22, 2021

(54) REFLECTIVE OPTICAL MODULATOR HAVING REDUCED TEMPERATURE SENSITIVITY

(71) Applicant: Nokia Solutions and Networks OY, Espoo (FI)

(72) Inventors: Stefano Grillanda, Springfield, NJ (US); Ting-Chen Hu, Westfield, NJ (US)

(73) Assignee: Nokia Solutions and Networks OY, Espoo (FI)

(21) Appl. No.: 16/745,468

(22) Filed: Jan. 17, 2020

(51) Int. Cl. H01S 5/00; G02B 6/12; H01S 5/02; G02F 1/01

(52) U.S. Cl. CPC H01S 5/0085; G02F 1/0115; H01S 5/0206; G02B 6/12004

(57) ABSTRACT

The temperature sensitivity of a reflective electro-absorption modulator can be reduced through the use, e.g., in the optical cavity thereof, of optical materials having positive and negative thermo-optic coefficients (TOCs). In some embodiments, a multiple-quantum-well structure of the modulator comprises positive-TOC materials, and a Bragg reflector bounding the optical cavity comprises one or more negative-TOC materials. In some embodiments, the thicknesses of the layers of positive- and negative-TOC materials are selected such that the average refractive index along the optical path through the modulator is approximately temperature independent. In some embodiments, the optical length of the optical cavity is an integer multiple of a nominal operating wavelength.

### BACKGROUND

### Field

Various example embodiments relate to optical communication equipment and, more specifically but not exclusively, to optical modulators.

### Description of the Related Art

This section introduces aspects that may help facilitate a better understanding of the disclosure. Accordingly, the statements of this section are to be read in this light and are not to be understood as admissions about what is in the prior art or what is not in the prior art.

An optical modulator is a device that can be used to manipulate a property of light, e.g., of an optical beam. Depending on which property of the optical beam is controlled, the optical modulator can be referred to as an intensity modulator, a phase modulator, a polarization modulator, a spatial-mode modulator, etc. A wide range of optical modulators is used, e.g., in optical transmitters employed in the telecom industry.

### SUMMARY OF SOME SPECIFIC EMBODIMENTS

In some embodiments, the temperature sensitivity of a reflective electro-absorption modulator can be reduced through the use, e.g., in the optical cavity thereof, of optical materials having positive and negative thermo-optic coefficients (TOCs). In some embodiments, a multiple-quantum-well structure of the modulator comprises positive-TOC materials, and a Bragg reflector bounding the optical cavity comprises one or more negative-TOC materials. In some embodiments, the thicknesses of the layers of positive- and negative-TOC materials are selected such that the average refractive index along the optical path through the modulator is approximately temperature independent. In some embodiments, the optical length of the optical cavity is about an integer multiple of a nominal operating wavelength.

According to an example embodiment, provided is an apparatus comprising: a substrate; and a reflective electro-absorption modulator that comprises: a first light reflector supported on the substrate at a first offset distance; a multiple-quantum-well structure supported on the substrate at a second offset distance that is greater than the first offset distance; a first layer of material having a first thermo-optic coefficient corresponding to a wavelength of light, the first layer located in an optical path of the light through the reflective electro-absorption modulator; and a second layer of material having a second thermo-optic coefficient corresponding to the wavelength of light, the second layer located in said optical path, the first and second thermo-optic coefficients having opposite signs.

According to another example embodiment, provided is an apparatus comprising: a substrate; and a reflective electro-absorption modulator physically fixed to the substrate and including an optical cavity to communicate light about normal to the substrate, the optical cavity comprising a stack of layers, the stack comprising: at least one first layer having a first thermo-optic coefficient near an operating temperature and near an operating wavelength of the reflective electro-absorption modulator; and at least one second layer having a second thermo-optic coefficient near the operating temperature and wavelength, the first and second thermo-optic coefficients having opposite signs.

### BRIEF DESCRIPTION OF THE DRAWINGS

Other aspects, features, and benefits of various disclosed embodiments will become more fully apparent, by way of example, from the following detailed description and the accompanying drawings, in which:

FIG. 1 shows a schematic cross-sectional side view of a surface-coupled electro-absorption modulator (SCEAM) according to an embodiment; and

FIG. 2 shows a block diagram of an optical transmitter that includes a plurality of SCEAMs of FIG. 1 according to an embodiment.

### DETAILED DESCRIPTION

Some embodiments of the present application may be able to use some features, apparatus, and/or methods disclosed in U.S. Pat. Nos. 10,411,807 and 9,853,416 and U.S. patent application Ser. No. 15/946,161, all of which are incorporated herein by reference in their entirety.

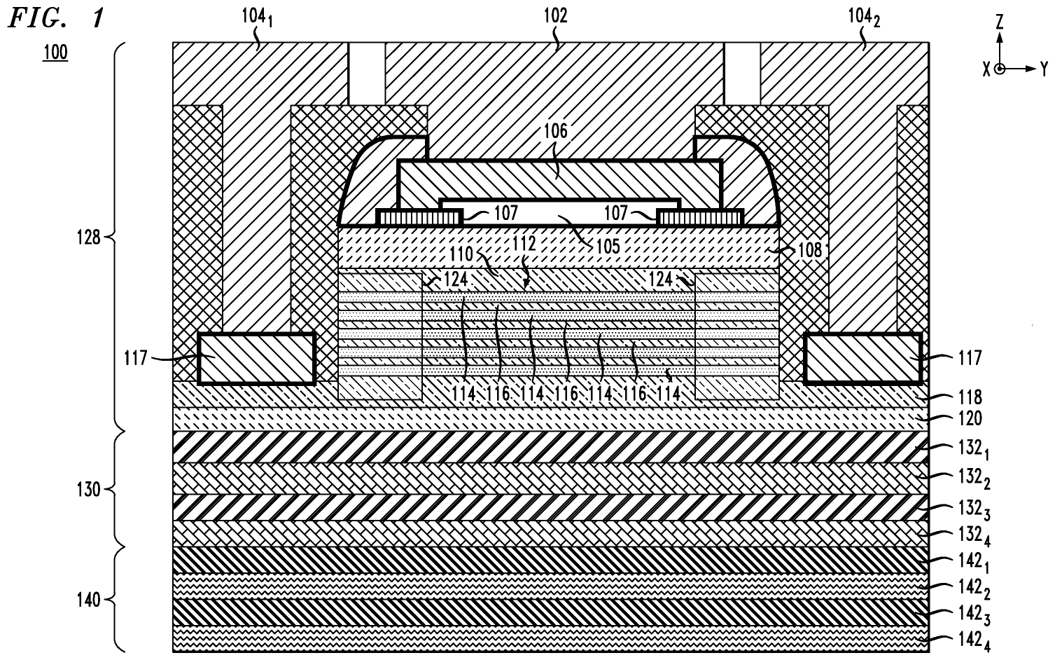

FIG. 1 shows a schematic cross-sectional side view of a surface-coupled electro-absorption modulator (SCEAM) 100 according to an embodiment.

SCEAM 100 is “surface-coupled” in the sense that, in operation, this device receives an input light beam and emits a modulated light beam in a direction that is substantially orthogonal (e.g., to within ±10 degrees) to a main plane of the device. A main plane of a device is substantially along a major, about planar surface of the device, and in FIG. 1, one such plane is about parallel to the XY-coordinate plane of the XYZ triad shown in FIG. 1. In an example embodiment, the XY-coordinate plane approximately corresponds to the main plane of the planar substrate on which the layered structures of SCEAM 100 are formed during fabrication. Due to this geometry, a large number of SCEAMs 100 can be manufactured on a single substrate (such as a semiconductor wafer), e.g., as described in the above-cited U.S. Pat. No. 10,411,807.

SCEAM 100 includes a plurality of relatively thin layers that are substantially parallel to the XY-coordinate plane. The direction orthogonal to those layers (i.e., substantially parallel to the Z-coordinate axis) may hereafter be referred to as the vertical or surface-normal direction. The directions parallel to those layers may hereafter be referred to as the horizontal or lateral directions. Some of the layers may include two or more sub-layers (not explicitly shown in FIG. 1) that differ from each other in chemical composition and/or the concentration and type of the introduced dopant(s). SCEAM 100 also includes metal electrodes 102 and 104₁-104₂ electrically connected to some of the layers as described in more detail below. In an example embodiment, the vertical size (or thickness) of SCEAM 100 is significantly smaller than its lateral size (e.g., depth and/or width).

In some embodiments, metal electrodes 104₁-104₂ can be electrically connected to one another by being parts of the same electrode having, e.g., an O-ring shape in the top view thereof (e.g., if viewed along the Z-coordinate axis).

SCEAM 100 comprises an optical cavity defined by a first mirror 106 and a second mirror. In some embodiments, a layer stack 140 can operate as the second mirror. In some other embodiments, a layer stack 130 can operate as the second mirror. In some embodiments, layer stack 140 can be optional, e.g., not present in SCEAM 100. In the illustrated embodiments, the second mirror is a partially transparent dielectric mirror that enables light of the nominal operating wavelength to be properly coupled into and/or out of the optical cavity of SCEAM 100. In other embodiments, the second mirror may be a different type of partially reflecting mirror.

In an example embodiment, the second mirror can be a distributed-Bragg-reflector (DBR) mirror. As known in the pertinent art, a DBR mirror can be formed, e.g., using a stack of semiconductor or dielectric layers, each having, e.g., an about quarter-wavelength thickness for an operating wavelength, with adjacent layers of the stack having alternating refractive indices.

In an example embodiment, mirror 106 is a metal (e.g., gold or gold-plated) mirror having relatively high (e.g., >99%) reflectivity at the nominal operating wavelength at the side of the mirror facing down (in the projection shown in FIG. 1). Mirror 106 is typically such that it does not allow light to pass therethrough at an operating wavelength. As a result, the shown embodiment of SCEAM 100 can typically be used only in reflection.

In some alternative embodiments, mirror 106 can be replaced by a suitable DBR mirror. In some embodiments, the second mirror may be optional, e.g., not present.

For illustration purposes and without any implied limitations, FIG. 1 shows an embodiment in which layer stack 130 comprises four layers 132₁-132₄. In an alternative embodiment, layer stack 130 can be implemented using a different (from four) number of constituent layers. In some embodiments, layer stack 130 can be replaced by a single layer of a similar material. Also for illustration purposes and without any implied limitations, in the embodiment of FIG. 1, layer stack 140 is shown as comprising four layers 142₁-142₄. In an alternative embodiment, layer stack 140 can be implemented using a different (from four) number of constituent layers. As already, indicated above, layer stack 140 may be completely absent in some embodiments.

In some embodiments, layers 142₁ and 142₃ may comprise silicon dioxide, and layers 142₃ and 142₄ may comprise silicon nitride. In other embodiments, layer stack 140 can be implemented using dielectrics of other suitable chemical composition or using semiconductor layers.

In an example embodiment, the optical cavity defined by the first mirror 106 and the second mirror 130 or 140 includes p-type semiconductor layers 108 and 110, n-type semiconductor layers 118 and 120, and a multiple-quantum-well (MQW) structure 112 sandwiched therebetween. MQW structure 112 comprises a stack of alternating relatively thin barrier layers 114 and well layers 116 for charge carriers, e.g., to form a stack of quantum wells. The well and barrier layers are typically made of different respective semiconductor alloys. In an example embodiment, the semiconductor materials of layers 114 and 116 are intrinsic semiconductors. Layer 108 may have a higher dopant concentration than layer 110, such that layers 108 and 110 can be referred to as p+ and p layers, respectively. Layer 120 may similarly have a higher dopant concentration than layer 118, such that layers 120 and 118 can be referred to as n+ and n layers, respectively.

In the embodiment shown in FIG. 1, the optical cavity defined by the first mirror 106 and the second mirror 130 or 140 also includes an optional dielectric layer 105 located between the first mirror and semiconductor layer 108. In an example embodiment, this layer may comprise SiO₂ or Si₃N₄. In an alternative embodiment, layer 105 can be absent.

A person of ordinary skill in the art will understand that the choices of (i) the semiconductor materials for layers 108, 110, 114, 116, 118, and 120 and (ii) the vertical distance between the first mirror 106 and the second mirror 130 or 140 may depend on the intended operating wavelength of SCEAM 100. For example, different telecommunications applications may use different embodiments of SCEAM 100 designed for the spectral bands located near 850 nm, 1300 nm, and 1550 nm, respectively.

In some embodiments, SCEAM 100 may include additional layers (not explicitly shown in FIG. 1) located between layers 120 and 132₁. An example of such layers can be one or more etch-stop layers and one or more buffer layers used in the manufacturing process, e.g., as explained in the above-cited U.S. Pat. No. 10,411,807.

In an example embodiment, the following inorganic semiconductor materials can be used to implement a portion of SCEAM 100: (i) Zn-doped In(x)Ga(1-x-y)Al(y)As for layer 108; (ii) Zn-doped In(x)Al(1-x)As for layer 110; (iii) In(x)Ga(1-x)As for layers 114; (iv) In(x)Al(1-x)As for layers 116; (v) Si-doped In(x)Al(1-x)As for layer 118; and (vi) Si-doped In(x)Ga(1-x-y)Al(y)As for layer 120. Here, the fractional concentrations x and y may vary in designs intended for different operating wavelengths, with 0<x<1 and 0<y<1, and 0<x+y<1. In alternative embodiments, other semiconductor materials (e.g., group III-V and/or SiGe alloys) and dopants can also be used.

In an example embodiment, layers 110 and 118 and MQW structure 112 form a p-i-n diode (also sometimes referred to as a “PIN diode”) that can be electrically biased using electrodes 102 and 104. Ohmic contact between electrode 102 and layer 110 can be created using metal contact pads 107 and layer 108 as known in the art. Ohmic contact between electrode(s) 104 and layer 118 can be created using metal contact pads 117 and an additional thin n+ or n++ semiconductor layer (not explicitly shown in FIG. 1) located between contact pads 117 and layer 118.

In operation, electrodes 102 and 104 of SCEAM 100 are electrically connected to apply to PIN diode 110/112/118 a combination of an appropriate reverse bias and a driving radio-frequency (RF) signal.

As used herein, the term “reverse bias” refers to an electrical configuration of a semiconductor-junction diode in which the n-type material is at a high electrical potential, and the p-type material is at a low electrical potential. The reverse bias typically causes the depletion layer to grow wider due to a lack of electrons and/or holes, which presents a high impedance path across the junction and substantially prevents a current flow therethrough. However, a very small reverse leakage current can still flow through the junction in the reverse-bias configuration.

Similarly, the term “forward bias” refers to an electrical configuration of a semiconductor-junction diode in which the n-type material is at a low potential, and the p-type material is at a high potential. If the forward bias is greater than the intrinsic voltage drop Vₚₙ across the corresponding p-i-n junction, then the corresponding potential barrier can be overcome by the electrical carriers, and a relatively large forward current can flow through the junction. For example, for silicon-based diodes the value of Vₚₙ is approximately 0.7 V. For germanium-based diodes, the value of Vₚₙ is approximately 0.3 V, etc.

In an example embodiment, the principle of operation of SCEAM 100 can be based on the so-called quantum-confined Stark effect (QCSE) due to which the optical absorption near the effective band edge of MQW structure 112 depends on the applied electric field. More specifically, the reverse bias applied to the PIN diode 110/112/118 causes MQW structure 112 to be subjected to an electric field of certain strength. The driving RF signal is typically an AC signal with a DC reverse bias offset, such that the effective bias remains reverse at any point in the driving cycle. During the positive swing of the driving RF signal, the electric-field strength increases relative to that at the DC bias point, thereby red-shifting the band edge. During the negative swing of the driving RF signal, the electric-field strength decreases relative to that at the DC bias point, thereby blue-shifting the band edge. These band-edge shifts change the light transmittance of MQW structure 112 at the carrier wavelength, thereby modulating the intensity of light that oscillates in the optical cavity between the first mirror 106 and the second mirror 130 or 140 and escapes from the optical cavity through the second mirror.

The lateral dimensions of the optical cavity in SCEAM 100 can be defined using an external aperture (not explicitly shown in FIG. 1) and/or ion-implanted regions 124. Ion-implanted regions 124 can be formed by implanting suitable ions (e.g., the hydrogen ions, H⁺) into MQW structure 112 around its periphery, e.g., as indicated in FIG. 1. The ion-implantation process disrupts, perturbs, and/or destroys the semiconductor lattice in regions 124, thereby inhibiting the flow of electrical current(s) therethrough and/or hindering the physical processes therein that are pertinent to the above-described optical functions of SCEAM 100. In an example embodiment, the middle portion of MQW structure 112 laterally bounded by regions 124 may have an approximately circular cross-sectional shape in a plane parallel to the XY-coordinate plane. In alternative embodiments, other cross-sectional geometric shapes are also possible.

Encapsulating and/or filler materials can be used as known in the pertinent art to cover and/or fill the gaps (if any) between the various layers, structures, and electrodes of SCEAM 100, thereby providing a substantially monolithic and mechanically robust overall device structure.

One beneficial optical characteristic of SCEAM 100 is that its operation can be substantially polarization-independent due to the optical, major-surface-coupled nature of this device. For comparison, waveguide-based semiconductor optical devices (e.g., lasers, amplifiers, modulators, and photodetectors) can be polarization-dependent, e.g., due to a relatively large difference in the group indices (i.e., effective refractive indices) of the transverse electric (TE) and transverse magnetic (TM) polarizations in the corresponding optical waveguides and/or quantum wells extended along segments of said optical waveguides. Waveguide-based electro-absorption modulators (EAMs) in particular can exhibit a large difference in the modulation depth for TE and TM polarizations due to the inherent anisotropy of the modulator structure with respect to those polarizations. This particular characteristic can make it relatively difficult to construct a polarization-diverse waveguide-based EAM device having a substantially polarization-independent response and/or capable of appropriately handling polarization-division-multiplexed (PDM) signals. Advantageously, the latter problem can be significantly alleviated or avoided altogether with the use of various embodiments of SCEAM 100.

Another beneficial characteristic of SCEAM 100 is that layer stack 130 can be used to significantly reduce the temperature sensitivity of the modulator, e.g., without introducing substantial polarization dependency in operation.

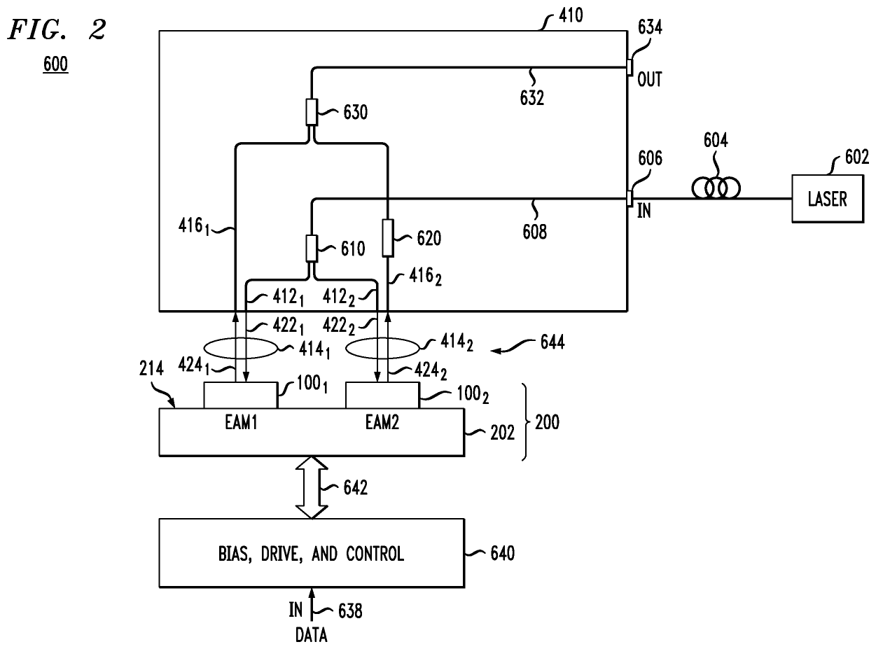

In general, temperature drifts and/or fluctuations can detrimentally affect the performance of an electro-absorption modulator, e.g., due to (i) thermally induced shifts of an optimal operating wavelength of the modulator and/or (ii) thermally induced distortions of the modulator's transfer function. These thermal effects may disadvantageously manifest themselves, e.g., as the relative closure of the “eye” in the eye diagram exhibited by the modulator. In the absence of active temperature control, temperature drifts and fluctuations can for example be caused by one or more of the following factors: (i) heat transfer from nearby circuits and/or devices; (ii) relatively high input laser power, which may be required by the power budget of the corresponding optical transmitter, e.g., to enable high-speed modulation and/or multilevel modulation formats; and (iii) variation of the optical power in the modulator. The optical power in the modulator may vary, for example, when it is impractical or difficult to control (e.g. stabilize) the optical power received by the modulator, which may be the case with remotely located laser sources connected to the modulator, e.g., by a relatively long span of optical fiber (e.g., 604, FIG. 2).

These and possibly other related problems in the state of the art can be addressed using various embodiments disclosed herein. In particular, some embodiments may provide stabilization, with respect to temperature changes, of certain characteristics of the modulator, which is achieved through the use of two or more layers of materials having opposite signs of the thermo-optic coefficient (TOC). This approach can be fully passive because it does not rely on the use of thermo-electric heaters and/or coolers. However, some embodiments may still use thermo-electric heater(s) and/or cooler(s) to further improve the performance characteristics of the modulator.

The refractive index n of a material typically varies with the temperature T, i.e., n=n(T). In the linear approximation, n(T) can be expressed as follows:

n(T)=n(T₀)+β×(T−T₀) (1)

where T₀ is a reference temperature, and β is the thermo-optic coefficient (TOC) of the material. For most materials, Eq. (1) models the behavior of the refractive index very well at relatively low temperatures, e.g., T<400 K. In these cases, the thermo-optic coefficient β is about constant. For higher temperatures, the refractive index of some materials may exhibit nonlinear behavior, in which cases higher order terms (e.g., second order or even higher-order polynomial terms) may need to be included in the mathematical model of n(T).

In a particular temperature range and wavelength range, some materials may have a positive thermo-optic coefficient β, whereas some other materials may have a negative thermo-optic coefficient β. For a material having a positive thermo-optic coefficient β, the refractive-index value increases with a temperature increase above T₀. In contrast, for a material having a negative thermo-optic coefficient β, the refractive-index value decreases with a temperature increase above T₀.

In an example embodiment, SCEAM 100 is constructed such as to have at least two layers of optical materials having TOCs of opposite sign in the temperature and wavelength ranges within which the modulator is designed to operate. Said at least two layers of such optical materials are placed in the optical path of the light propagating through SCEAM 100, e.g., as layers extending along a major surface of the SCEAM 100. For example, some of the materials may be located in the optical cavity of SCEAM 100. Some of the materials may be used to form parts of one or both of the mirrors that bound the optical cavity of SCEAM 100, etc.

In an example embodiment, MQW structure 112 comprises a stack of materials having positive thermo-optic coefficients. These materials can be, e.g., the above-mentioned III-V materials and/or SiGe semiconductor materials. In such an embodiment, layer stack 130 may comprise at least one material having a negative thermo-optic coefficient. Example materials that can be used for the this purpose (i.e., materials having negative thermo-optic coefficients) include but are not limited to: (i) TiO₂ (n=2.18, β=−2·10⁻⁴ K⁻¹); (ii) BaF₂ (n=1.46, β=−1·10⁻⁵ K⁻¹); (iii) CaF₂ (n=1.43, β=−1.2·10⁻⁵ K⁻¹); (iv) MgF₂ (n=1.37, β=−3·10⁻⁵ K⁻¹); (v) poly(methyl methacrylate) or PMMA (n=1.48, β=−1.3·10⁻⁴K⁻¹); and (vi) a SU-8 polymer (n=1.56, β=−1.1·10⁻⁴K⁻¹). Herein, SU-8 refers to a commercially available epoxy-based photoresist material. The refractive-index values and β values given in the parentheses correspond to room temperature and the spectral C-band, i.e., near 1530-1565 nm.

For example, in one possible embodiment, layers 132₁ and 132₃ may comprise PMMA, and layers 132₃ and 132₄ may comprise SU-8. In another possible embodiment, layers 132₁ and 132₃ may comprise CaF₂, and layers 132₃ and 132₄ may comprise TiO₂.

In some embodiments, layer stack 130 can be replaced by a single layer of a suitable negative-TOC material.

In various alternative embodiments, some other layers in SCEAM 100 can be made of materials having negative thermo-optic coefficients. Such other layers may include, e.g., one or more of layers 105, 108, 118, and 120.

Embodiments in which MQW structure 112 comprises one or more materials having negative thermo-optic coefficients while layer stack 130 comprises one or more materials having positive thermo-optic coefficients are also possible.

In some embodiments, the thicknesses of the various layers in SCEAM 100 can be such as to approximately satisfy the following mathematical relationship:

$${\sum }_{j} {t}_{j} {β}_{j} = 0 \qquad ( 2 )$$

where tⱼ is the optical thickness of the j-th layer in SCEAM 100; βⱼ is the thermo-optic coefficient of the j-th layer; and j is the integer index used to designate different layers in the plurality of layers of SCEAM 100. The optical path length for passing normally through a layer is the product of the physical thickness of the layer and the refractive index of the layer. Note that Eq. (2) can be satisfied because some of the βⱼ values are positive while some other of the βⱼ values are negative. A person of ordinary skill in the art will understand that, in embodiments for which Eq. (2) is approximately satisfied, the effective (e.g., averaged along the optical path) index of refraction of SCEAM 100 is approximately temperature independent. This approximate temperature independence is achieved because the thermally induced positive refractive-index changes of some of the materials in SCEAM 100 are counterbalanced by the thermally induced negative refractive-index changes of the other materials therein.

In some embodiments, the total optical length (corresponding to the Z dimension in FIG. 1) of the optical cavity in SCEAM 100 can be an integer multiple of a nominal operating wavelength of the modulator. In such embodiments, in addition to the reduced temperature sensitivity, a relatively large (e.g., maximum) extinction ratio for the modulator can be achieved at nominal operating wavelengths.

FIG. 2 shows a block diagram of an optical transmitter 600 according to an embodiment. Transmitter 600 comprises: (i) a SCEAM array 200 that includes two instances of SCEAM 100 labeled 100₁ and 100₂, respectively; (ii) a planar lightwave circuit 410; (iii) a lens array 644 that includes lenses 414₁ and 414₂; (iv) an electrical circuit 640; and (v) a laser 602. Laser 602 is connected to an input port 606 of waveguide circuit 410 using an optical fiber 604. Electrical circuit 640 is connected to SCEAM array 200 using an electrical bus 642. In operation, circuit 640 can (i) provide respective bias voltages to SCEAMs 100₁ and 100₂ and (ii) generate respective electrical RF drive signals to be applied to SCEAMs 100₁ and 100₂ in response to an electrical data-input signal 638.

In addition to the SCEAMs 100₁ and 100₂, array 200 includes a device carrier 202. The orientation of SCEAMs 100₁ and 100₂ in array 200 is such that mirrors 130 or 140 of the individual SCEAMs are facing away from a surface 214 of device carrier 202, on which the SCEAMs are mounted. Electrical connections between electrodes 102 and 104 of SCEAMs 100₁ and 100₂ and circuit 640 can be provided by patterned conducting (such as metal) layers located within the body and/or on surface 214 of device carrier 202. In various embodiments, device carrier 202 can be implemented using any one or any suitable combination of the following: one or more substrates, one or more redistribution layers (RDLs), one or more interposers, one or more laminate plates, and one or more circuit sub-mounts, etc.

In an example embodiment, optical transmitter 600 can operate as follows.

Laser 602 operates to generate a CW optical beam that is coupled, by way of fiber 604 and input port 606 into waveguide 608 of circuit 410, e.g., the laser may be quite remote relative to the array 200. Waveguide 608 directs the received CW light to an optical splitter 610 that splits it into two portions and couples the two portions into waveguides 412₁ and 412₂, respectively. In an example embodiment, optical splitter 610 can be a 3-dB power splitter/combiner. In an alternative embodiment, optical splitter 610 having a different split ratio can similarly be used if appropriate or necessary for the intended type of modulation.

Waveguide 412₁ outputs the light received from splitter 610 as an optical output beam 422₁. Lens 414₁ couples beam 422₁ into SCEAM 100₁, where it is modulated to generate a corresponding modulated optical output beam 424₁. The modulation is performed using the corresponding electrical RF drive signal generated by circuit 640 in response to the data-input signal 638, with the drive signal being applied to SCEAM 100₁ by way of electrical bus 642. Lens 414₁ then couples beam 424₁ into waveguide 416₁ of circuit 410.

Waveguide 412₂ similarly outputs the light received from splitter 610 as an optical output beam 422₂. Lens 414₂ couples beam 422₂ into SCEAM 100₂, where it is modulated to generate a corresponding modulated optical output beam 424₂. The modulation is performed using the corresponding electrical RF drive signal generated by circuit 640 in response to the data-input signal 638, with the drive signal being applied to SCEAM 100₂ by way of electrical bus 642. Lens 414₂ then couples beam 424₂ into waveguide 416₂ of circuit 410.

An optical combiner 630 operates to (i) combine the light of modulated optical beams 424₁ and 424₂ with a relative phase shift imposed by a phase shifter 620 and (ii) couple the resulting combined optical beam into an optical waveguide 632. Waveguide 632 then directs the received optical beam to an optical output port (e.g., comprising a fiber connector) 634 of circuit 410, from which it can be further directed to external circuits, such as a remote optical receiver (not explicitly shown in FIG. 6).

A person of ordinary skill in the art will recognize that splitter 610, waveguides 412 and 416, phase shifter 620, and combiner 630 are parts of an optical interferometer that can be used to generate more-advanced modulation formats, e.g., compared to the ON-OFF keying (OOK) modulation conventionally used with electro-absorption modulators. For example, PAM-4 modulation can be achieved as described in the above-cited U.S. Pat. No. 10,411,807.

The relative phase shift imposed by phase shifter 620 is a fixed phase shift that depends on the intended modulation format. For example, in some embodiments, the relative phase shift can be about 180 degrees. In some other embodiments, the relative phase shift can be, e.g., about 90 degrees. In some embodiments, phase shifter 620 can be a tunable phase shifter that enables a slow adjustment of the relative phase shift, e.g., to compensate for fabrication variances, temperature fluctuations, and possibly other instabilities that can affect the relative phase shift in the two arms of the interferometer. Herein, the term “slow” should be construed to mean on a much greater time scale than the inverse baud rate.

Alternative embodiments of an optical transmitter can constructed using one or more SCEAMs 100, e.g., as described in the above-cited U.S. Pat. No. 10,411,807.

According to an example embodiment disclosed above, e.g., in the summary section and/or in reference to any one or any combination of some or all of FIGS. 1-2, provided is an apparatus comprising: a substrate (e.g., 202, FIG. 2); and a reflective electro-absorption modulator (e.g., 100₁, FIG. 2) that comprises: a first light reflector (e.g., 106, FIG. 1) supported on the substrate at a first offset distance; a multiple-quantum-well structure (e.g., 112, FIG. 1) supported on the substrate at a second offset distance that is greater than the first offset distance; a first layer of material (e.g., 114, FIG. 1) having a first thermo-optic coefficient corresponding to a wavelength of light, the first layer located in an optical path of the light through the reflective electro-absorption modulator; and a second layer of material (e.g., 132₁, FIG. 1) having a second thermo-optic coefficient corresponding to the wavelength of light, the second layer located in said optical path, the first and second thermo-optic coefficients having opposite signs.

In some embodiments of the above apparatus, the reflective electro-absorption modulator further comprises a second light reflector (e.g., 130 or 140, FIG. 1) supported on the substrate such that the multiple-quantum-well structure is located between the first and second light reflectors, the second light reflector being partially transparent at the wavelength of light.

In some embodiments of any of the above apparatus, the second light reflector (e.g., 140, FIG. 1) is a distributed Bragg reflector.

In some embodiments of any of the above apparatus, the multiple-quantum-well structure includes the first layer; and wherein the second light reflector (e.g., 130, FIG. 1) includes the second layer.

In some embodiments of any of the above apparatus, the first light reflector has a reflectivity that is greater than 90% (or greater than 95%) at the wavelength of light.

In some embodiments of any of the above apparatus, the reflective electro-absorption modulator comprises: a first plurality of distinct layers (e.g., 114, 116, FIG. 1) located in said optical path, each distinct layer of the first plurality having a positive thermo-optic coefficient corresponding to the wavelength of light; and a second plurality of distinct layers (e.g., 132₁, 132₂, FIG. 1) located in said optical path, each distinct layer of the second plurality having a negative thermo-optic coefficient corresponding to the wavelength of light.

In some embodiments of any of the above apparatus, the first plurality of distinct layers comprises at least two distinct layers made of different respective materials.

In some embodiments of any of the above apparatus, the second plurality of distinct layers comprises at least two distinct layers made of different respective materials.

In some embodiments of any of the above apparatus, the reflective electro-absorption modulator comprises a second light reflector (e.g., 130, FIG. 1) that includes the second plurality of distinct layers.

In some embodiments of any of the above apparatus, thicknesses of the distinct layers are such (e.g., in accordance with Eq. (2)) that an effective refractive index of the reflective electro-absorption modulator corresponding to the wavelength of light is substantially temperature independent at an operating temperature thereof.

In some embodiments of any of the above apparatus, the reflective electro-absorption modulator comprises a second light reflector, the first and second light reflectors defining an optical cavity whose optical length is an integer multiple of the wavelength of light.

In some embodiments of any of the above apparatus, the second thermo-optic coefficient has a negative value; and wherein the second layer comprises at least one of TiO₂, BaF₂, CaF₂, and MgF₂.

In some embodiments of any of the above apparatus, the second thermo-optic coefficient has a negative value; and wherein the second layer comprises a polymer.

In some embodiments of any of the above apparatus, the apparatus further comprises an optical data transmitter (e.g., 600, FIG. 2) that includes the reflective electro-absorption modulator.

In some embodiments of any of the above apparatus, the optical data transmitter comprises a laser source (e.g., 602, FIG. 2) connected via a span of optical fiber (e.g., 604, FIG. 2) to apply the light to the reflective electro-absorption modulator.

According to another example embodiment disclosed above, e.g., in the summary section and/or in reference to any one or any combination of some or all of FIGS. 1-2, provided is an apparatus comprising: a substrate (e.g., 202, FIG. 2); and a reflective electro-absorption modulator (e.g., 100₁, FIG. 2) physically fixed to the substrate and including an optical cavity (e.g., defined by 106 and (130 or 140), FIG. 1) to communicate light about normal (e.g., to within ±10 degrees) to the substrate, the optical cavity comprising a stack of layers, the stack comprising: at least one first layer (e.g., 114/116, FIG. 1) having a first thermo-optic coefficient near an operating temperature and near an operating wavelength of the reflective electro-absorption modulator; and at least one second layer (e.g., 132, FIG. 1) having a second thermo-optic coefficient near the operating temperature and the operating wavelength, the first and second thermo-optic coefficients having opposite signs.

In some embodiments, the term “near an operating temperature” may refer to a temperature interval of ca.±40 K with respect to said operating temperature. For example, in some specific embodiments, an example operating temperature can be approximately 35 C, and the corresponding example temperature interval near said operating temperature can be from about −5 C to about 80 C. In alternative embodiments, narrower temperature ranges are also possible.

In some embodiments, the term “near an operating wavelength” may refer to a wavelength range of ca.±0.5 nm with respect to said operating wavelength. For example, in a single-wavelength configuration, e.g., when only one SCEAM 100 is being used, the wavelength range near the operating wavelength can be approximately the same as the bandwidth of the transmitted data stream. As such, in the case of a 100-GHz bandwidth, the corresponding wavelength range may be close to ca. 1 nm in spectral width. In some other embodiments, the term “near an operating wavelength” may refer to a wider wavelength range. Such embodiments may be suitable, e.g., for a multi-wavelength configuration, e.g., when an array of SCEAMs 100 is being used, with each of said SCEAMs operating at a different respective wavelength. In this case, the spectrum of the SCEAM array may take up to a few tens of nanometers. As such, the corresponding wavelength range can be, e.g., between about 1535 nm and about 1575 nm, or between about 1260 nm and about 1360 nm.

In some embodiments of the above apparatus, the at least one first layer includes a first substack of distinct layers (e.g., 114/116, FIG. 1), each distinct layer of the first substack having a positive thermo-optic coefficient near the operating temperature and the operating wavelength; and wherein the at least one second layer includes a second substack of distinct layers (e.g., 132₁-132₄, FIG. 1), each distinct layer of the second substack having a negative thermo-optic coefficient near the operating temperature and wavelength.

In some embodiments of any of the above apparatus, the optical path length of the optical cavity near the operating wavelength is substantially temperature independent near the operating temperature.

As used herein, the term “substantially temperature independent” refers to a relatively small temperature-related rate of change of the optical path length. For example, in some embodiments, said rate of change can be smaller than ca. one quarter of the operating wavelength per 10 K.

While this disclosure includes references to illustrative embodiments, this specification is not intended to be construed in a limiting sense. Various modifications of the described embodiments, as well as other embodiments within the scope of the disclosure, which are apparent to persons skilled in the art to which the disclosure pertains are deemed to lie within the principle and scope of the disclosure, e.g., as expressed in the following claims.

Unless explicitly stated otherwise, each numerical value and range should be interpreted as being approximate as if the word “about” or “approximately” preceded the value or range.

It will be further understood that various changes in the details, materials, and arrangements of the parts which have been described and illustrated in order to explain the nature of this disclosure may be made by those skilled in the art without departing from the scope of the disclosure, e.g., as expressed in the following claims.

The use of figure numbers and/or figure reference labels (if any) in the claims is intended to identify one or more possible embodiments of the claimed subject matter in order to facilitate the interpretation of the claims. Such use is not to be construed as necessarily limiting the scope of those claims to the embodiments shown in the corresponding figures.

Reference herein to “one embodiment” or “an embodiment” means that a particular feature, structure, or characteristic described in connection with the embodiment can be included in at least one embodiment of the disclosure. The appearances of the phrase “in one embodiment” in various places in the specification are not necessarily all referring to the same embodiment, nor are separate or alternative embodiments necessarily mutually exclusive of other embodiments. The same applies to the term “implementation.”

Unless otherwise specified herein, the use of the ordinal adjectives “first,” “second,” “third,” etc., to refer to an object of a plurality of like objects merely indicates that different instances of such like objects are being referred to, and is not intended to imply that the like objects so referred-to have to be in a corresponding order or sequence, either temporally, spatially, in ranking, or in any other manner.

Throughout the detailed description, the drawings, which are not to scale, are illustrative only and are used in order to explain, rather than limit the disclosure. The use of terms such as height, length, width, top, bottom, is strictly to facilitate the description of the embodiments and is not intended to limit the embodiments to a specific orientation. For example, height does not imply only a vertical rise limitation, but is used to identify one of the three dimensions of a three dimensional structure as shown in the figures. Such “height” would be vertical where the layers are horizontal but would be horizontal where the layers are vertical, and so on. Similarly, while all figures show the different layers as horizontal layers such orientation is for descriptive purpose only and not to be construed as a limitation.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

The described embodiments are to be considered in all respects as only illustrative and not restrictive. In particular, the scope of the disclosure is indicated by the appended claims rather than by the description and figures herein. All changes that come within the meaning and range of equivalency of the claims are to be embraced within their scope.

The description and drawings merely illustrate the principles of the disclosure. It will thus be appreciated that those of ordinary skill in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering the art, and are to be construed as being without limitation to such specifically recited examples and conditions. Moreover, all statements herein reciting principles, aspects, and embodiments of the disclosure, as well as specific examples thereof, are intended to encompass equivalents thereof.

As used in this application, the term “circuitry” may refer to one or more or all of the following: (a) hardware-only circuit implementations (such as implementations in only analog and/or digital circuitry); (b) combinations of hardware circuits and software, such as (as applicable): (i) a combination of analog and/or digital hardware circuit(s) with software/firmware and (ii) any portions of hardware processor(s) with software (including digital signal processor(s)), software, and memory(ies) that work together to cause an apparatus, such as a mobile phone or server, to perform various functions); and (c) hardware circuit(s) and or processor(s), such as a microprocessor(s) or a portion of a microprocessor(s), that requires software (e.g., firmware) for operation, but the software may not be present when it is not needed for operation.” This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in server, a cellular network device, or other computing or network device.

It should be appreciated by those of ordinary skill in the art that any block diagrams herein represent conceptual views of illustrative circuitry embodying the principles of the disclosure.

What is claimed is:

1. An apparatus comprising:
a substrate; and
a reflective electro-absorption modulator physically fixed to the substrate and including an optical cavity to communicate light about normal to the substrate, the optical cavity comprising a stack of layers, the stack comprising:
at least one first layer having a first thermo-optic coefficient near an operating temperature and near an operating wavelength of the reflective electro-absorption modulator; and
at least one second layer having a second thermo-optic coefficient near the operating temperature and wavelength, the first and second thermo-optic coefficients having opposite signs.

2. The apparatus of claim 1, wherein the reflective electro-absorption modulator further comprises first and second reflectors and a quantum-well structure, the quantum-well structure being located between the first and second light reflectors, the second light reflector being partially transparent near the operating wavelength.

3. The apparatus of claim 2, wherein the second light reflector includes a distributed Bragg reflector.

4. The apparatus of claim 3,
wherein the quantum-well structure includes the at least one first layer; and
wherein the second light reflector includes the at least one second layer.

5. The apparatus of claim 1, wherein the first light reflector has a reflectivity that is greater than 90% near the operating wavelength.

6. The apparatus of claim 1,
wherein the at least one first layer includes a first substack of distinct layers, each distinct layer of the first substack having a positive thermo-optic coefficient near the operating temperature and wavelength; and
wherein the at least one second layer includes a second substack of distinct layers, each distinct layer of the second substack having a negative thermo-optic coefficient near the operating temperature and wavelength.

7. The apparatus of claim 6, wherein the first substack of distinct layers comprises at least two distinct layers of different respective materials.

8. The apparatus of claim 6, wherein the second substack of distinct layers comprises at least two distinct layers of different respective materials.

9. The apparatus of claim 6, wherein the reflective electro-absorption modulator comprises a second light reflector that includes the second substack of distinct layers.

10. The apparatus of claim 6, wherein the optical path length of the optical cavity near the operating wavelength is substantially temperature independent near the operating temperature.

11. The apparatus of claim 10, wherein the optical cavity has an optical path length that is an integer multiple of the operating wavelength near the operating temperature.

12. The apparatus of claim 1,
wherein the second thermo-optic coefficient has a negative value; and
wherein the at least one second layer comprises at least one of TiO₂, BaF₂, CaF₂, and MgF₂.

13. The apparatus of claim 1,
wherein the second thermo-optic coefficient has a negative value; and
wherein the at least one second layer comprises a polymer.

14. The apparatus of claim 1, further comprising an optical data transmitter that includes the reflective electro-absorption modulator.

15. The apparatus of claim 14, wherein the optical data transmitter comprises a laser source connected via a span of optical fiber to apply the light to the reflective electro-absorption modulator.
